(19) United States
(12) Patent Application Publication
(10) Pub. No.: US 2026/0190581 A1
(43) Pub. Date: Jul. 2, 2026

(54) Display Device

(71) Applicant: LG Display Co., Ltd., Seoul (KR)

(72) Inventors: Dae Young Seo, Paju-si (KR); Hun Jang, Paju-si (KR); Byung Hyun Lee, Paju-si (KR); Tae Yong Kim, Paju-si (KR); Su Min Lee, Paju-si (KR)

(21) Appl. No.: 19/432,692

(22) Filed: Dec. 24, 2025

(30) Foreign Application Priority Data
Dec. 31, 2024 (KR) 10-2024-0202671

(51) Int. Cl. H10H 29/49; H10D 86/40; H10D 86/60; H10H 29/32; H10H 29/34

(52) U.S. Cl. CPC H10H 29/49; H10D 86/443; H10D 86/481; H10D 86/60; H10H 29/32; H10H 29/34

(57) ABSTRACT

Embodiments disclose a display device including a substrate in which pixel regions spaced apart from each other and transmission regions disposed between the pixel regions are defined, a scan line extending in a first direction on the substrate, and data lines extending in a second direction intersecting the first direction on the substrate. Each of the plurality of pixel regions includes a plurality of sub-pixels, and each of the plurality of sub-pixels includes a first main pixel and a first redundancy pixel that output first light, a second main pixel and a second redundancy pixel that output second light, and a third main pixel and a third redundancy pixel that output third light. The first main pixel, the first redundancy pixel, the second main pixel, the second redundancy pixel, the third main pixel, and the third redundancy pixel are sequentially disposed in the first direction or the second direction.

### CROSS-REFERENCE TO RELATED APPLICATION

The present application claims priority to Republic of Korea Patent Application No. 10-2024-0202671, filed on Dec. 31, 2024, which is incorporated herein by reference in its entirety.

### BACKGROUND

### Field

Embodiments relate to a transparent display device using a light-emitting diode (LED).

### Discussion of Related Art

Display devices used in computer monitors, televisions (TVs), mobile phones, and the like include an organic light-emitting display (OLED) device which emits light by itself and the like and a liquid crystal display (LCD) device which requires a separate light source, and the like.

The scope of application of the display devices is becoming more diverse, including not only computer monitors and TVs but also personal portable devices, and research on display devices having large display areas and having reduced volumes and weights is being conducted.

Further, recently, display devices including light-emitting diodes (LEDs) are attracting attention as next-generation display devices. Since LEDs are formed of inorganic materials rather than organic materials, LEDs are highly reliable and thus have a longer lifespan than liquid crystal display devices or organic light-emitting display devices. Further, LEDs not only have a fast lighting speed, but also have excellent light-emitting efficiency, have excellent stability due to excellent impact resistance, and may display high luminance images.

### SUMMARY

One or more embodiments of the present disclosure are directed to providing a display device in which pixels of the same color are disposed at constant intervals.

One or more embodiments of the present disclosure are directed to providing a transparent display device having high transmittance.

One or more embodiments of the present disclosure are directed to providing a display device in which an opaque pixel region and a plurality of lines overlap to maximize or at least increase an area of a transmission region.

The objects of the present disclosure are not limited to the above-described objects, and other objects that are not mentioned will be clearly understood by those skilled in the art from the following description.

A display device according to one or more embodiments includes: a substrate in which a plurality of pixel regions spaced apart from each other and a plurality of transmission regions disposed between the plurality of pixel regions are defined; a scan line extending in a first direction on the substrate; and a plurality of data lines extending in a second direction intersecting the first direction on the substrate, wherein the plurality of pixels each include a plurality of sub-pixels, the plurality of sub-pixels each include a first main pixel and a first redundancy pixel that output first light, a second main pixel and a second redundancy pixel that output second light, and a third main pixel and a third redundancy pixel that output third light, and the first main pixel, the first redundancy pixel, the second main pixel, the second redundancy pixel, the third main pixel, and the third redundancy pixel are sequentially disposed in the first direction or the second direction.

### BRIEF DESCRIPTION OF THE DRAWINGS

The above and other objects, features and advantages of the present invention will become more apparent to those of ordinary skill in the art by describing embodiments thereof in detail with reference to the accompanying drawings, in which:

FIG. 1 is a schematic configuration diagram of a display device according to one or more embodiments of the present disclosure.

FIG. 2A is a partial cross-sectional view of the display device according to one or more embodiments of the present disclosure.

FIG. 2B is a perspective view of a tiling display device according to one or more embodiments of the present disclosure.

FIG. 3 is a schematic enlarged plan view of a display region of the display device according to one or more embodiments of the present disclosure.

FIG. 4 is a view showing a state in which sub-pixels of the same color are not disposed adjacent to each other in a pixel region.

FIG. 5 is a view showing a state in which the sub-pixels of the same color are disposed adjacent to each other in the pixel region.

FIG. 6 is a view showing an active layer in the pixel region according to one or more embodiments of the present disclosure.

FIG. 7 is a view showing a scan line, a driving transistor, a first transistor, and a second transistor in the pixel region according to one or more embodiments of the present disclosure.

FIG. 8 is a view showing a low-potential power line in the pixel region according to one or more embodiments of the present disclosure.

FIG. 9 is a view showing data lines in the pixel region according to one or more embodiments of the present disclosure.

FIG. 10 is a view showing a high-potential power line in the pixel region according to one or more embodiments of the present disclosure.

FIG. 11 is a view showing a light-emitting element, a first connection electrode, and a second connection electrode according to one or more embodiments of the present disclosure.

FIG. 12 is a cross-sectional view of the sub-pixel of the display device according to one or more embodiments of the present disclosure.

FIG. 13 is a pixel circuit diagram of the display device according to one or more embodiments of the present disclosure.

FIG. 14 is a pixel circuit diagram of a display device according to one or more other embodiments of the present disclosure.

FIG. 15 is an enlarged plan view of a display region of the display device according to one or more other embodiments of the present disclosure.

FIG. 16 is a pixel circuit diagram of a display device according to one or more other embodiments of the present disclosure.

FIG. 17 is an enlarged plan view of a display region of the display device according to one or more other embodiments of the present disclosure.

### DETAILED DESCRIPTION

Advantages and features of the present disclosure and methods of achieving them will become apparent with reference to the following embodiments, which are described in detail, in conjunction with the accompanying drawings. However, the present disclosure is not limited to the embodiments to be described below and may be implemented in various different forms, the embodiments are only provided to completely disclose the present disclosure and completely convey the scope of the present disclosure to those skilled in the art.

Since the shapes, sizes, proportions, angles, numbers, and the like disclosed in the drawings for describing the embodiments of the present disclosure are only exemplary, the present disclosure is not limited to the items shown in the drawings. The same reference number indicates the same components throughout the disclosure. Further, in describing the present disclosure, when it is determined that a detailed description of related known technology may unnecessarily obscure the gist of the present disclosure, the detailed description thereof will be omitted. When ‘providing,’ ‘including,’ ‘having,’ ‘comprising,’ and the like mentioned in the present disclosure are used, other parts may be added unless ‘only’ is used. A case in which a component is expressed in a singular form may include a plural form unless explicitly stated otherwise.

In interpreting a component, the component is interpreted as including a margin of error even when there is no separate explicit description of the margin of error.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

A case where an element or a layer is described as being on another element or layer includes both cases in which the element or layer is directly on the other element or layer and cases in which still another layer or element is interposed between the other element and the element.

Although first, second, and the like are used to describe various components, these components are not limited by these terms. These terms are only used to distinguish one component from another. Accordingly, a first component mentioned below may also be a second component within the technical spirit of the present disclosure.

The same reference number indicates the same components throughout the disclosure.

The size and thickness of each component shown in the drawings are shown for convenience of description and are not necessarily limited to sizes and thicknesses of the components shown in the present disclosure.

Features of various embodiments of the present disclosure may be partially or entirely combined with each other, and technically, various linkages and operations are possible, and the embodiments may be implemented independently of each other or together in a related relationship.

Hereinafter, the present disclosure will be described with reference to the drawings.

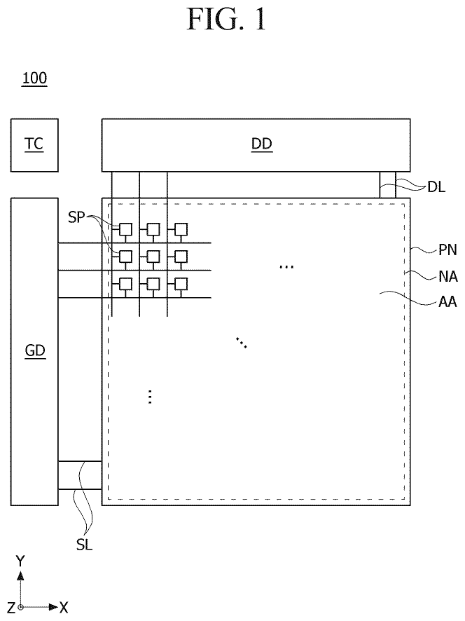

FIG. 1 is a schematic configuration diagram of a display device according to one or more embodiments of the present disclosure. For convenience of description, FIG. 1 shows only a display panel PN, a gate driver GD, a data driver DD, and a timing controller TC among various components of the display device 100.

Referring to FIG. 1, the display device 100 includes the display panel PN including a plurality of sub-pixels SP, the gate driver GD and the data driver DD which supply various signals to the display panel PN, and the timing controller TC which controls the gate driver GD and the data driver DD.

The gate driver GD supplies a plurality of scan signals to a plurality of scan lines SL according to a plurality of gate control signals provided from the timing controller TC. In FIG. 1, one gate driver GD is shown as being disposed spaced apart from one side of the display panel PN, but the number and disposition of gate drivers GD are not limited thereto.

The data driver DD supplies a data voltage to a plurality of data lines DL according to a plurality of data control signals and image data provided from the timing controller TC. The data driver DD may convert the image data into a data voltage using a reference gamma voltage, and supply the converted data voltage to the plurality of data lines DL.

The timing controller TC aligns image data input from the outside and supplies the image data to the data driver DD. The timing controller TC may generate gate control signals and data control signals using synchronization signals input from the outside, for example, a dot clock signal, a data enable signal, and a horizontal/vertical synchronization signal. Further, the timing controller TC may control the gate driver GD and the data driver DD by respectively supplying the generated gate control signals and data control signals to the gate driver GD and the data driver DD.

The display panel PN is a configuration for displaying an image to a user and includes a plurality of sub-pixels SP. In the display panel PN, the plurality of scan lines SL and the plurality of data lines DL intersect each other, and the plurality of sub-pixels SP may be formed at intersecting points of the scan lines SL and the data lines DL.

A display region AA and a non-display region NA may be defined in the display panel PN.

The display region AA is a region where an image is displayed in the display device 100. The plurality of sub-pixels SP constituting a plurality of pixels PX and pixel circuits for driving the plurality of sub-pixels SP may be disposed in the display region AA. The plurality of sub-pixels SP are minimum units constituting the display region AA, and n sub-pixels SP may form one pixel PX. A thin film transistor or the like for driving a plurality of light-emitting elements 120 may be disposed in each of the plurality of sub-pixels SP. The plurality of light-emitting elements 120 may be defined differently depending on the type of display panel PN. For example, when the display panel PN is an inorganic light-emitting display panel, the light-emitting element 120 may be a light-emitting diode (LED) or micro light-emitting diode (micro-LED).

A plurality of signal lines which transmit various signals to the plurality of sub-pixels SP are disposed in the display region AA. For example, the plurality of signal lines may include the plurality of data lines DL which supply the data voltages to each of the plurality of sub-pixels SP, the plurality of scan lines SL which supply the scan signals to each of the plurality of sub-pixels SP, and the like. The plurality of scan lines SL may extend in one direction in the display region AA and may be connected to the plurality of sub-pixels SP, and the plurality of data lines DL may extend in a direction different from the one direction in the display region AA and may be connected to the plurality of sub-pixels SP. In addition, the low-potential power line, the high-potential power line, and the like may be further disposed in the display region AA, but the present disclosure is not limited thereto.

The non-display region NA is a region where an image is not displayed and may be defined as a region extending from the display region AA. In the non-display region NA, link lines and pad electrodes for transmitting signals to the sub-pixels SP of the display region AA, driving integrated circuits IC such as a gate driver IC and a data driver IC, or the like may be disposed.

Meanwhile, the non-display region NA may be located on a rear surface of the display panel PN, that is, on a surface without the sub-pixels SP, or may be omitted, but is not limited to what is shown in the drawings.

Meanwhile, drivers such as the gate driver GD, the data driver DD, and the timing controller TC may be connected to the display panel PN in various ways. For example, the gate driver GD may be mounted in the non-display region NA using a gate in panel (GIP) method, or may be mounted between the plurality of sub-pixels SP in the display region AA using a gate in active area (GIA) method.

For example, the data driver DD and the timing controller TC may be formed on a separate flexible film and printed circuit board, and the display panel PN, the data driver DD, and the timing controller TC may be electrically connected by bonding the flexible film and the printed circuit board to the pad electrodes formed in the non-display region NA of the display panel PN.

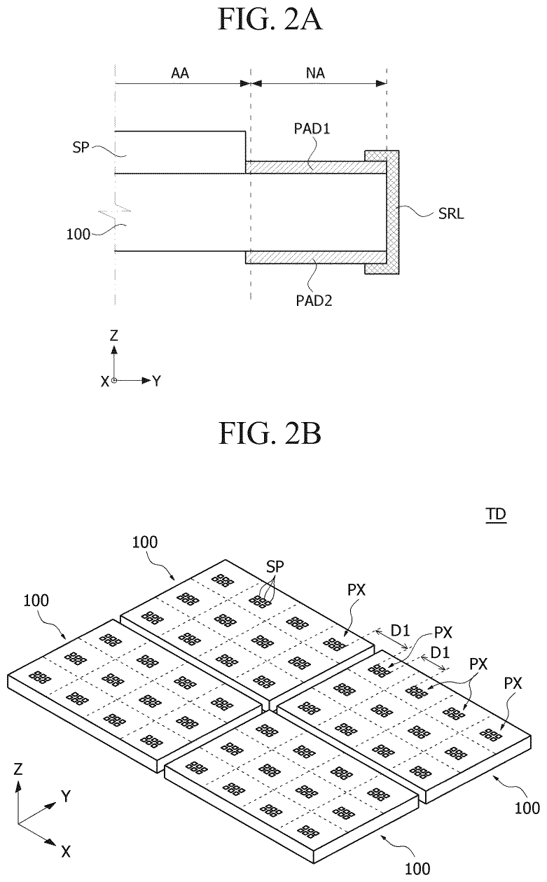

For another example, when the gate driver GD is mounted inside the display region AA using the GIA method, and a side line SRL which connects the signal lines on a front surface of the display panel PN to the pad electrodes on the rear surface of the display panel PN is formed to bond the flexible film and the printed circuit board to the rear surface of the display panel PN, the non-display region NA on the front surface of the display panel PN may be minimized or at least reduced. Accordingly, when the gate driver GD, the data driver DD, and the timing controller TC are connected to the display panel PN in the above-described manner, a zero bezel where substantially no bezel is present may be implemented, and a more detailed description refers to FIGS. 2A and 2B.

FIG. 2A is a partial cross-sectional view of the display device according to one or more embodiments of the present disclosure. FIG. 2B is a perspective view of a tiling display device according to one or more embodiments of the present disclosure.

A plurality of pad electrodes for transmitting various signals to the plurality of sub-pixels SP are disposed in the non-display region NA of the display panel PN. For example, first pad electrodes PAD1 which transmit signals to the plurality of sub-pixels SP are disposed in the non-display region NA on the front surface of the display panel PN, and second pad electrodes PAD2 electrically connected to driving components such as the flexible film and the printed circuit board are disposed in the non-display region NA on the rear surface of the display panel PN.

In this case, although not shown in the drawings, various signal lines connected to the plurality of sub-pixels SP, for example, the scan lines SL, the data lines DL, or the like may extend from the display region AA to the non-display region NA and may be electrically connected to the first pad electrodes PAD1.

Further, the side line SRL is disposed along a side surface of the display panel PN. The side line SRL may electrically connect the first pad electrodes PAD1 on the front surface of the display panel PN and the second pad electrodes PAD2 on the rear surface of the display panel PN. Accordingly, signals may be transmitted from driving components on the rear surface of the display panel PN to the plurality of sub-pixels SP through the second pad electrodes PAD2, the side line SRL, and the first pad electrodes PAD1. Accordingly, the area of the non-display region NA on the front surface of the display panel PN may be minimized or at least reduced by disposing the driving components on the rear surface of the display panel PN and forming a signal transmission path between the front and rear surfaces of the display panel PN.

Further, referring to FIG. 2B, a tiling display device TD having a large screen may be implemented by connecting a plurality of display devices 100. In this case, when the tiling display device TD is implemented using the display device 100 having a minimized or at least reduced bezel as shown in FIG. 2A, a seam region between the display devices 100 where no image is displayed may be minimized or at least reduced and thus display quality may be improved.

For example, one pixel PX may include a plurality of sub-pixels SP, and an interval D1 between the outermost pixel PX of one display device 100 and the outermost pixel PX of another display device 100 adjacent thereto may be implemented the same as an interval D1 between the pixels PX in one display device 100. Accordingly, since the intervals of the pixels PX between the display devices 100 are configured to be constant, the seam region may be minimized or at least reduced.

However, FIGS. 2A and 2B are exemplary, and the display device 100 according to one or more embodiments of the present disclosure may be a general display device in which a bezel is present, but is not limited thereto.

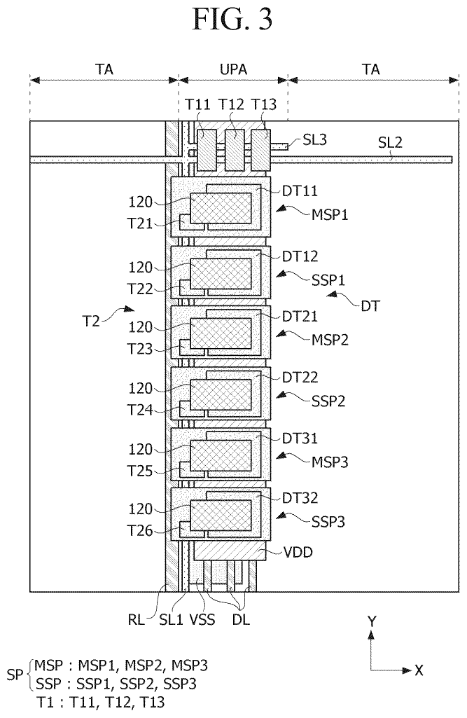

FIG. 3 is a schematic enlarged plan view of the display region of the display device according to one or more embodiments of the present disclosure.

Referring to FIG. 3, a pixel region UPA formed with pixels and a transmission region TA surrounding the pixel region UPA are formed in the display region AA. As the light-emitting elements 120 driven by a pixel circuit are formed in the pixels of the display region AA, a plurality of pixel regions UPA may be substantially opaque regions, and a plurality of transmission regions TA may be substantially transparent regions. In this case, the pixel region UPA may also be defined as a light-emitting region, as it is a region where light emitted from the light-emitting elements 120 is displayed. Further, the pixel region UPA is a region where the pixel circuit is formed, and thus may also be defined as a circuit region.

The plurality of pixel regions UPA are regions where the light-emitting elements 120 are disposed and display images. The plurality of pixel regions UPA may be disposed spaced apart from each other with the plurality of transmission regions TA therebetween. For example, the plurality of pixel regions UPA may be disposed to form a plurality of rows and columns.

The pixel region UPA may include a plurality of sub-pixels SP. The plurality of sub-pixels SP may include main sub-pixels MSP and redundancy sub-pixels SSP. According to one or more embodiments, three main pixels MSP and three redundancy pixels SSP may be disposed, but the number of each sub-pixel is not limited thereto.

The main pixels MSP may include a first main pixel MSP1 which outputs first light, a second main pixel MSP2 which outputs second light, and a third main pixel MSP3 which outputs third light. The redundancy pixels SSP may include a first redundancy pixel SSP1 which outputs the first light, a second redundancy pixel SSP2 which outputs the second light, and a third redundancy pixel SSP3 which outputs the third light. The main pixels MSP can be defined by the main sub-pixels and the redundancy pixels SSP can be defined by the redundancy sub-pixels.

The first main pixel MSP1 and the first redundancy pixel SSP1 may output first light of the same wavelength range, the second main pixel MSP2 and the second redundancy pixel SSP2 may output second light of the same wavelength range, and the third main pixel MSP3 and the third redundancy pixel SSP3 may output third light of the same wavelength range.

The first light may be light in a red wavelength range, the second light may be light in a green wavelength range, and the third light may be light in a blue wavelength range. However, the embodiments are not limited thereto. For example, the first light may be light in a blue wavelength range, the second light may be light in a red wavelength range, and the third light may be light in a green wavelength range.

The driving transistors DT of a plurality of main pixels MSP and redundancy pixels SSP may be arranged in a row in a second direction (a Y-axis direction). The plurality of main pixels MSP and redundancy pixels SSP may be disposed in a row while overlapping a region where the data lines DL, a low-potential power line VSS, and a high-potential power line VDD are disposed.

According to one or more embodiments, the first main pixel MSP1, the first redundancy pixel SSP1, the second main pixel MSP2, the second redundancy pixel SSP2, the third main pixel MSP3, and the third redundancy pixel SSP3 may be sequentially disposed in a row. Being sequentially disposed may mean that the pixels are disposed in the order listed above.

An interval between the first main pixel MSP1 and the first redundancy pixel SSP1 may be the same as an interval between the second main pixel MSP2 and the second redundancy pixel SSP2. With this configuration, there is an advantage in that the main pixels MSP and the redundancy pixels SSP which emit the same color are disposed adjacent to each other at constant intervals and thus a color may be uniformly distributed.

A plurality of micro light-emitting elements may be epitaxially grown on a wafer and then transferred to a panel. Accordingly, in some micro light-emitting elements, defective pixels which do not emit light or abnormally emit light due to various defects may occur. Accordingly, the redundancy pixels SSP may be provided to prepare for defective pixels after transfer to the panel. Accordingly, when the main pixel MSP is found to be defective through an inspection process, the redundancy pixel SSP may be configured to be driven. Accordingly, any one of or both the main pixel MSP and the redundancy pixel SSP may be used in the panel.

For example, when any one of the main pixel and the redundancy pixel is defective and thus only the other operates, there is a problem that intervals between the sub-pixels are not constant and thus the color is not uniform.

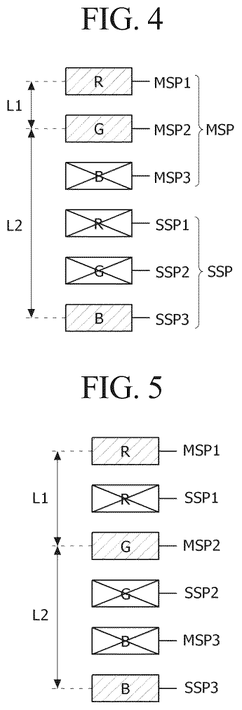

Referring to FIG. 4, when the main pixels MSP are disposed together on one side and the redundancy pixels SSP are disposed together on the other side, the third redundancy pixel SSP3 may be designed to be driven when the third main pixel MSP3 is determined to be defective. However, in this case, an interval L2 between the second main pixel MSP2 and the third redundancy pixel SSP3 becomes too far compared to an interval L1 between the first main pixel MSP1 and the second main pixel MSP2. Accordingly, a problem that image quality and readability deteriorate may occur

On the other hand, referring to FIG. 5, when the main pixels MSP and the redundancy pixels SSP are alternately disposed, it can be seen that the interval L2 between the second main pixel MSP2 and the third redundancy pixel SSP3 may become relatively short even when the third main pixel MSP3 is defective, and thus color uniformity may be enhanced.

Referring to FIG. 3 again, the pixel region UPA may overlap lines extending in a column direction among the plurality of lines, for example, the data lines DL and/or reference lines RL. An area of the transmission region TA may be secured in the entire display region AA by forming the pixel region UPA in a region where a plurality of opaque lines are disposed. Specifically, the pixel region UPA where the plurality of sub-pixels SP are disposed may be a region which has low transmittance and is substantially opaque due to the configurations of the pixel circuit and the light-emitting elements 120 disposed in the plurality of sub-pixels SP.

According to one or more embodiments, the plurality of sub-pixels SP of the pixel region UPA may be disposed to overlap the opaque lines extending in the column direction, for example, the data lines DL, the low-potential power line VSS, and the high-potential power line VDD. Accordingly, an area of the opaque region in the entire display region AA may be reduced and the area of the transmission region TA may be maximized or at least reduced by disposing the plurality of sub-pixels SP of the pixel region UPA so that the plurality of sub-pixels SP overlap the plurality of lines.

According to one or more embodiments, the reference line RL may be manufactured using an active layer of a second transistor T2 to manufacture a transparent line. Accordingly, the reference line RL may be disposed so that at least a portion thereof does not overlap the sub-pixel SP. Since the reference line RL does not overlap the sub-pixel SP, the opaque pixel region UPA may be further reduced.

Each of the plurality of sub-pixels SP may include a pixel circuit connected to the data lines DL, the reference lines RL, the low-potential power line VSS, and the high-potential power line VDD. The pixel circuit may include a plurality of transistors.

According to one or more embodiments, among the transistors constituting the pixel circuit, a first transistor T1 connected to the data line DL may be shared by the main pixel MSP and the redundancy pixel SSP. For example, the first main pixel MSP1 and the first redundancy pixel SSP1 may share a 1 -1 transistor T11. Accordingly, when the 1-1 transistor T11 is turned on in response to the scan signal, the data voltage may be simultaneously applied to gate electrodes of the first main pixel MSP1 and the first redundancy pixel SSP1.

The second main pixel MSP2 and the second redundancy pixel SSP2 may share a 1-2 transistors T12. The third main pixel MSP3 and the third redundancy pixel SSP3 may share a 1-3 transistor T13.

With this configuration, as each main pixel and redundancy pixel use the first transistor T1 in common, the size of the sub-pixel SP may be reduced. Accordingly, the area of the transmission region TA may be increased by reducing the area of the pixel region UPA.

The scan line SL may include a first scan line SL1 extending in the second direction (the Y-axis direction) the same as the plurality of data lines DL, a second scan line SL2 extending in a first direction (an X-axis direction) intersecting the second direction, and a third scan line SL3 branching from the second scan line SL2 and disposed parallel to the second scan line SL2.

The first direction may be a horizontal line direction and the second direction may be a vertical line direction, but are not limited thereto. For example, the first direction may be the vertical line direction and the second direction may be the horizontal line direction.

An active layer of the first transistor T1 may overlap the second scan line SL2 and the third scan line SL3 to have a dual-gate structure. Accordingly, leakage current blocking performance may be improved.

The plurality of transmission regions TA are regions in the display region AA, excluding a region where the plurality of lines and the plurality of pixel regions UPA are disposed, and have relatively high transmittance. In the transmission region TA, light is transmitted, and a background located at the rear surface of the display device 100 may be seen from the front surface of the display device 100. The plurality of transmission regions TA may be disposed spaced apart from each other with the plurality of lines and the plurality of pixel regions UPA therebetween. The plurality of transmission regions TA may be disposed to surround the plurality of pixel regions UPA. Accordingly, the display device 100 according to one or more embodiments of the present disclosure may be implemented as a transparent display device 100 by including the plurality of transmission regions TA.

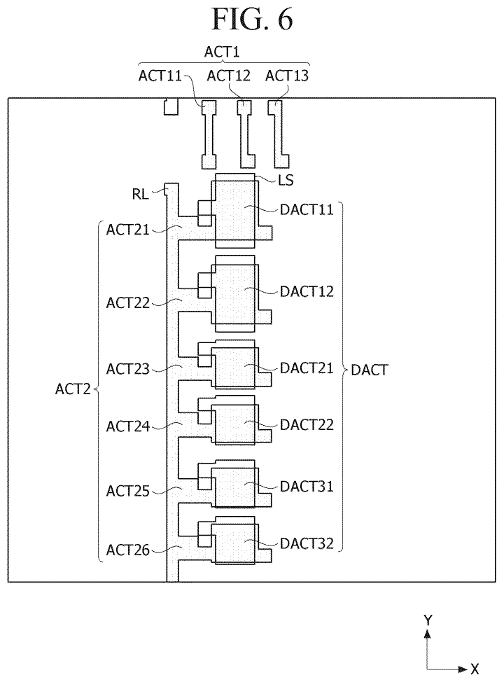

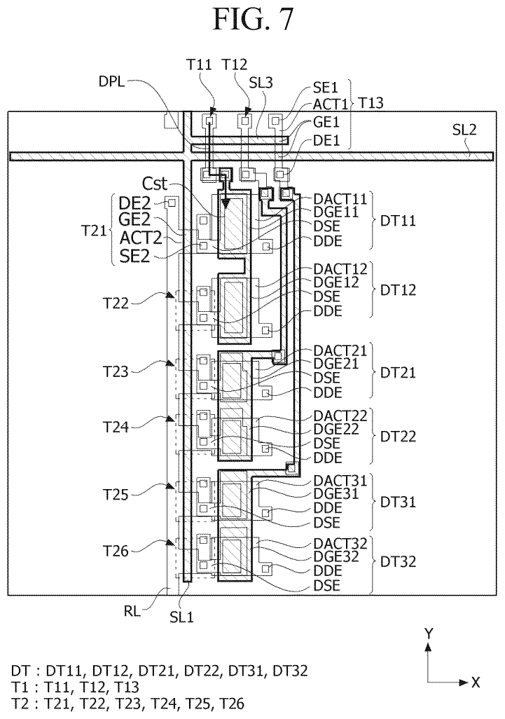

FIG. 6 is a view showing the active layer in the pixel region according to one or more embodiments of the present disclosure. FIG. 7 is a view showing the scan line, the driving transistor, the first transistor, and the second transistor in the pixel region according to one or more embodiments of the present disclosure.

Referring to FIG. 6, as described above, the pixel region UPA may include three main pixels and three redundancy pixels. A plurality of first active layers ACT11, ACT12, and ACT13 of the first transistors may extend in the second direction (the Y-axis direction) and may be spaced apart from each other in the first direction (the X-axis direction). A plurality of driving active layers DACT11, DACT12, DACT21, DACT22, DACT31, and DACT32 of the driving transistors may be connected to second active layers ACT21, ACT22, ACT23, ACT24, ACT25, and ACT26 of the second transistors. Further, the second active layers ACT21, ACT22, ACT23, ACT24, ACT25, and ACT26 of the second transistors may be connected to each other. Accordingly, signals output from the driving transistors DT may be applied to the reference lines RL through the second transistors T2. Light blocking layers LS may be disposed under the driving active layers of the driving transistors DT.

Referring to FIG. 7, the driving transistors DT include a 1-1 driving transistor DT11 of the first main pixel MSP1, a 1-2 driving transistor DT12 of the first redundancy pixel SSP1, a 2-1 driving transistor DT21 of the second main pixel MSP2, a 2-2 driving transistor DT22 of the second redundancy pixel SSP2, a 3-1 driving transistor DT31 of the third main pixel MSP3, and a 3-2 driving transistor DT32 of the third redundancy pixel SSP3. Each driving transistor may include a driving active layer DACT, a gate electrode DGE, a driving drain electrode DDE, and a driving source electrode DSE. A plurality of capacitors Cst may be disposed to respectively overlap the driving transistors DT.

The first transistors T1 may include a 1-1 transistor T11 connected to the 1-1 driving transistor DT11 and the 1-2 driving transistor DT12, a 1-2 transistor T12 connected to the 2-1 driving transistor DT21 and the 2-2 driving transistor DT22, and a 1-3 transistor T13 connected to the 3-1 driving transistor DT31 and the 3-2 driving transistor DT32.

According to one or more embodiments, the 1-1 driving transistor DT11 of the first main pixel MSP1 and the 1-2 driving transistor DT12 of the first redundancy pixel SSP1 may share the first transistor T1. A 1-1 driving gate electrode DGE11 of the 1-1 driving transistor DT11 and a 1-2 driving gate electrode DGE12 of the 1-2 driving transistor DT12 may be connected to each other. Accordingly, a data voltage applied from the 1-1 transistor T11 may be applied in common to the 1-1 driving gate electrode DGE11 of the 1-1 driving transistor DT11 and the 1-2 driving gate electrode DGE12 of the 1-2 driving transistor DT12 as shown by an arrow DPL.

A 2-1 driving gate electrode DGE21 of the 2-1 driving transistor DT21 and a 2-2 driving gate electrode DGE22 of the 2-2 driving transistor DT22 may be connected to each other. Accordingly, a data voltage applied from the 1-2 transistors T12 may be applied in common to the 2-1 driving gate electrode DGE21 of the 2-1 driving transistor DT21 and the 2-2 driving gate electrode DGE22 of the 2-2 driving transistor DT22.

A 3-1 driving gate electrode DGE31 of the 3-1 driving transistor DT31 and a 3-2 driving gate electrode DGE32 of the 3-2 driving transistor DT32 may be connected to each other. Accordingly, a data voltage applied from the 1-3 transistor T13 may be applied in common to the 3-1 driving gate electrode DGE31 of the 3-1 driving transistor DT31 and the 3-2 driving gate electrode DGE32 of the 3-2 driving transistor DT32.

With this configuration, since two driving transistors are connected to one first transistor T1, the number of transistors may be reduced and thus the area of the pixel region UPA may be reduced. Accordingly, the area of the transmission region TA may be increased.

The scan line SL may include the second scan line SL2 and the third scan line SL3 branching from the plurality of pixel regions UPA. Accordingly, the first active layer ACT1 of the first transistor T1 may extend in the second direction and overlap each of the second scan line SL and the third scan line SL3 to form a dual-gate structure. The third scan line SL3 may also be referred to as an auxiliary scan line. The third scan line SL3 may be shorter than the second scan line SL2.

Each second transistor T2 may include a second active layer ACT2, a second gate electrode GE2, a second drain electrode DE2, and a second source electrode SE2, and may be disposed adjacent to the driving transistor DT. The scan line SL may include the first scan line SL1 extending in the second direction (the Y-axis direction) and overlapping the second active layer ACT2 of the second transistor to form the second gate electrode GE2.

The second transistors T2 may include a 2-1 transistor T21 connected to the 1-1 driving transistor DT11, a 2-2 transistor T22 connected to the 1-2 driving transistor DT12, a 2-3 transistor T23 connected to the 2-1 driving transistor DT21, a 2-4 transistor T24 connected to the 2-2 driving transistor DT22, a 2-5 transistor T25 connected to the 3-1 driving transistor DT31, and a 2-6 transistor T26 connected to the 3-2 driving transistor DT32.

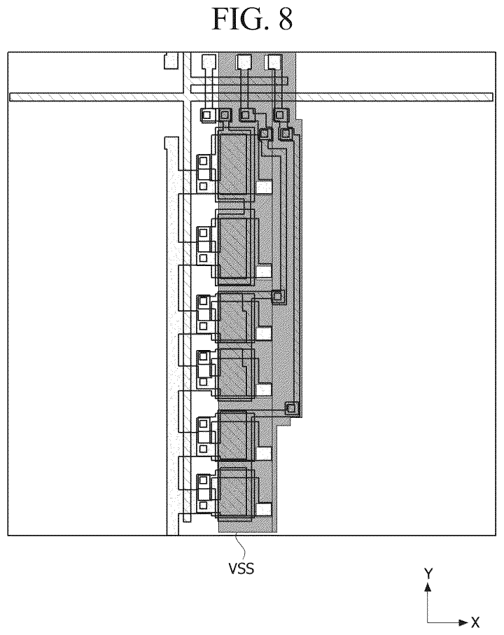

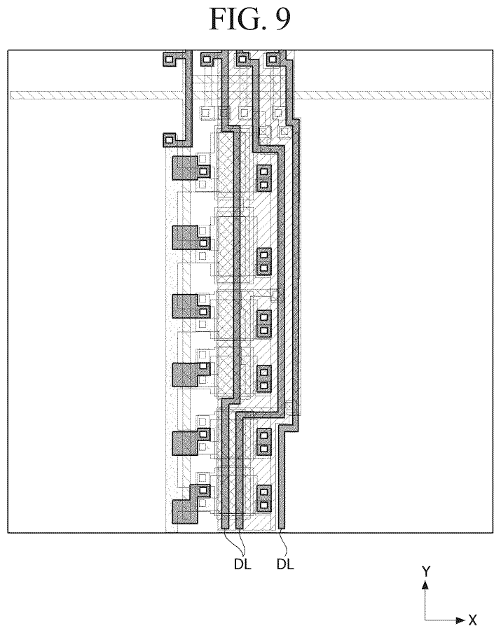

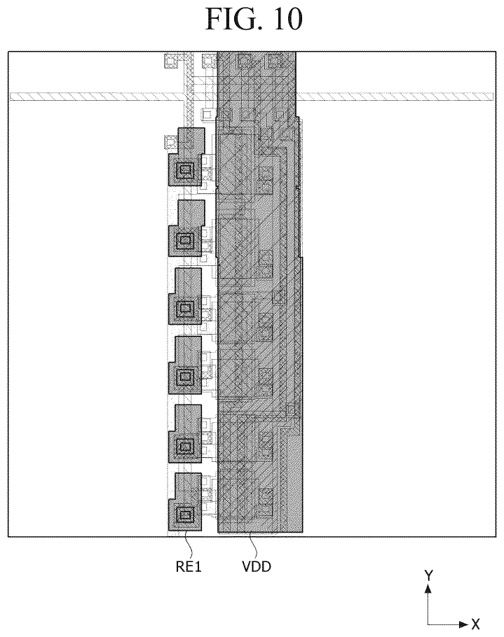

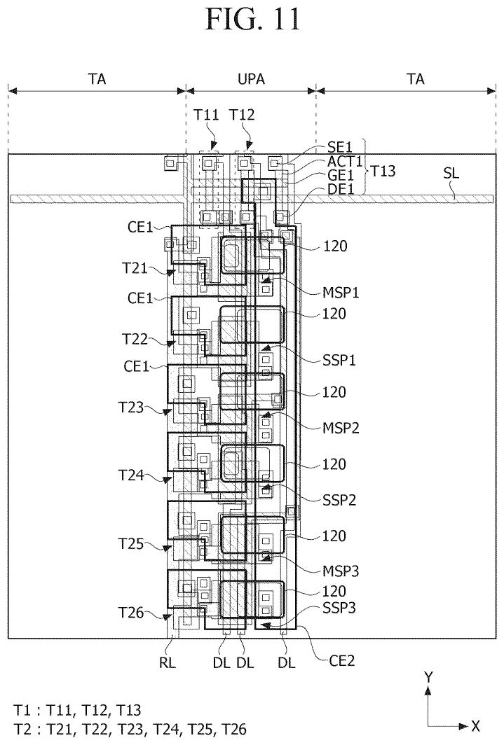

FIG. 8 is a view showing the low-potential power line in the pixel region according to one or more embodiments of the present disclosure. FIG. 9 is a view showing the data lines in the pixel region according to one or more embodiments of the present disclosure. FIG. 10 is a view showing the high-potential power line in the pixel region according to one or more embodiments of the present disclosure.

Referring to FIGS. 8 to 10, the low-potential power line VSS may be disposed on the driving transistors DT and the capacitors Cst. The data lines DL may be disposed on the low-potential power line VSS. The high-potential power line VDD may be disposed on the data lines DL. Insulating layers may be disposed between the low-potential power line VSS, the data lines DL, and the high-potential power line VDD to electrically insulate each layer.

The low-potential power line VSS, the data lines DL, and the high-potential power line VDD may be disposed to overlap the sub-pixels SP. The low-potential power line VSS may be disposed between the storage capacitors Cst and the driving transistors DT and the plurality of data lines DL, and overlap a region where the plurality of data lines DL are disposed. The low-potential power line VSS may overlap the plurality of data lines DL, the driving transistors DT, and the storage capacitors Cst. The high-potential power line VDD may overlap the plurality of data lines DL, the driving transistors DT, the storage capacitors Cst, and the low-potential power line VSS. The high-potential power line VDD may be disposed between the light-emitting elements 120 and the data lines DL, and overlap the region where the plurality of data lines DL are disposed. Accordingly, the area of the transmission region TA may be increased by minimizing or at least reducing the area of the pixel region UPA.

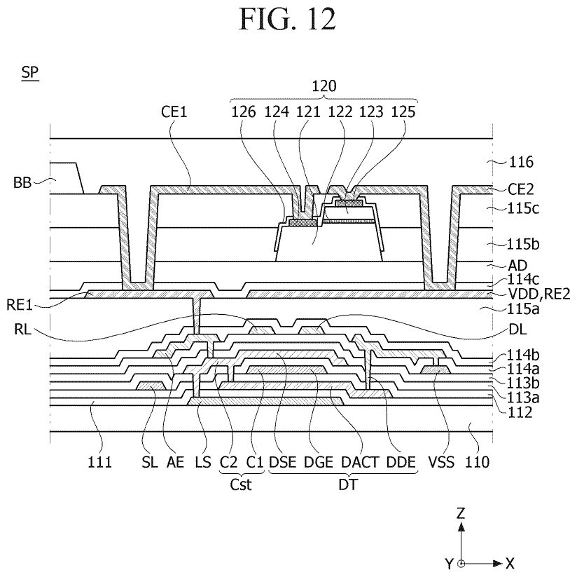

FIG. 11 is an enlarged plan view of a display region of the display device according to one or more embodiments of the present disclosure. FIG. 12 is a cross-sectional view of a sub-pixel of the display device according to one or more embodiments of the present disclosure.

Referring to FIGS. 11 and 12, each of the plurality of sub-pixels SP includes a pixel circuit and one or more light-emitting elements 120. The pixel circuit may include a plurality of transistors T1, T2, and DT, and a storage capacitor Cst, and supply a driving current to the light-emitting elements 120. For example, the pixel circuit may include a first transistor T1, a second transistor T2, a driving transistor DT, and the storage capacitor Cst. Further, the plurality of sub-pixels SP disposed in one pixel region UPA may be connected to the scan line SL, the plurality of data lines DL, the reference line RL, the high-potential power line VDD, and the low-potential power line VSS, and may receive various signals.

A substrate 110 is a configuration for supporting various components included in the display device 100 and may be made of an insulating material. For example, the substrate 110 may be made of glass, resin, or the like. Further, the substrate 110 may include a polymer or plastic, or may be made of a material having flexibility.

A light blocking layer LS is disposed in each of the plurality of sub-pixels SP on the substrate 110. The light blocking layer LS blocks light incident on the driving active layer DACT of the driving transistor DT from a lower portion of the substrate 110. Since the light blocking layer LS blocks light incident on the driving active layer DACT of the driving transistor DT, leakage current may be minimized or at least reduced.

A buffer layer 111 is disposed on the substrate 110 and the light blocking layer LS. The buffer layer 111 may reduce the permeation of moisture or impurities through the substrate 110. The buffer layer 111 may be composed of, for example, a single layer or multiple layers of silicon oxide (SiOₓ) or silicon nitride (SiNₓ), but is not limited thereto. However, the buffer layer 111 may be omitted depending on the type of substrate 110 or the type of transistor, but is not limited thereto.

The driving transistor DT and the second transistor T2 are disposed in each of the plurality of sub-pixels SP on the buffer layer 111.

The driving transistor DT, the first transistor T1, and the second transistor T2 of each of the plurality of sub-pixels SP may be P-type thin film transistors or N-type thin film transistors. For example, in the P-type thin film transistor, since holes move from a source electrode to a drain electrode, current may flow from the source electrode to the drain electrode. In the N-type thin film transistor, since electrons move from the source electrode to the drain electrode, current may flow from the drain electrode to the source electrode. Hereinafter, the following description assumes that the driving transistor DT, the first transistor T1, and the second transistor T2 are P-type thin film transistors which allow current to flow from the source electrode to the drain electrode, but the present disclosure is not limited thereto.

First, the driving transistor DT is disposed in each of the plurality of sub-pixels SP on the buffer layer 111. The driving transistor DT may be disposed between the plurality of data lines DL and the substrate 110 and electrically connected to the first transistor T1. The driving transistor DT is a transistor for controlling the driving current supplied to the light-emitting element 120. The driving transistors DT of the plurality of sub-pixels SP may be disposed in a column in the column direction.

The driving transistor DT includes the driving active layer DACT, the driving gate electrode DGE, the driving source electrode DSE, and the driving drain electrode DDE.

The driving active layer DACT is disposed on the buffer layer 111. The driving active layer DACT may be made of a semiconductor material such as an oxide semiconductor, amorphous silicon, or polysilicon, but is not limited thereto.

A gate insulating layer 112 is disposed on the driving active layer DACT. The gate insulating layer 112 is an insulating layer for electrically insulating the driving active layer DACT and the driving gate electrode DGE, and may be composed of a single layer or multiple layers of silicon oxide (SiOₓ) or silicon nitride (SiNₓ), but is not limited thereto.

The driving gate electrode DGE is disposed on the gate insulating layer 112. The driving gate electrode DGE may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

A first interlayer insulating layer 113a is disposed on the driving gate electrode DGE. A contact hole is formed in the first interlayer insulating layer 113a for connecting the driving source electrode DSE to the driving active layer DACT. The first interlayer insulating layer 113a is an insulating layer for protecting the configurations under the first interlayer insulating layer 113a, and may be composed of a single layer or multiple layers of silicon oxide (SiOₓ) or silicon nitride (SiNₓ), but is not limited thereto.

The driving source electrode DSE is disposed on the first interlayer insulating layer 113a. The driving source electrode DSE is electrically connected to the driving active layer DACT through the contact hole formed in the first interlayer insulating layer 113a. Further, the driving source electrode DSE may be electrically connected to the second transistor T2. The driving source electrode DSE may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

A second interlayer insulating layer 113b is disposed on the driving source electrode DSE. The second interlayer insulating layer 113b is an insulating layer for protecting the configurations under the second interlayer insulating layer 113b, and may be composed of a single layer or multiple layers of silicon oxide (SiOₓ) or silicon nitride (SiNₓ), but is not limited thereto.

A first passivation layer 114a is disposed on the second interlayer insulating layer 113b. The first passivation layer 114a is an insulating layer for protecting the configurations under the first passivation layer 114a, and may be composed of a single layer or multiple layers of silicon oxide (SiOₓ) or silicon nitride (SiNₓ), but is not limited thereto.

The driving drain electrode DDE is disposed on the first passivation layer 114a. The driving drain electrode DDE is electrically connected to the driving active layer DACT through a contact hole formed in the first passivation layer 114a, the first interlayer insulating layer 113a, and the second interlayer insulating layer 113b. Further, the driving drain electrode DDE may be electrically connected to the low-potential power line VSS through a contact hole formed in the first passivation layer 114a. The driving drain electrode DDE may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

Next, the first transistor T1 is disposed in each of the plurality of sub-pixels SP on the buffer layer 111. The first transistor T1 is a transistor which transmits a data voltage Vdata to a gate electrode of the driving transistor DT, and may be referred to as a switching transistor. In this case, the plurality of first transistors T1 of the plurality of sub-pixels SP in the one pixel region UPA are disposed to overlap the scan lines SL, and may be disposed in a row in a row direction.

Specifically, the scan lines SL may extend in the row direction on the gate insulating layer 112 and may be disposed across the plurality of pixel regions UPA.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be made of a semiconductor material such as an oxide semiconductor, amorphous silicon, or polysilicon, but is not limited thereto.

The first gate electrode GE1 is disposed on the gate insulating layer 112. The first gate electrode GE1 may be electrically connected to the scan line SL. For example, the first gate electrode GE1 may be integrally formed with the scan line SL. The first gate electrode GE1 may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

The first drain electrode DE1 is disposed between the first interlayer insulating layer 113a and the second interlayer insulating layer 113b. The first drain electrode DE1 is electrically connected to the first active layer ACT1 through a contact hole formed in the first interlayer insulating layer 113a and the gate insulating layer 112. Further, the first drain electrode DE1 may be electrically connected to the second gate electrode GE2 of the second transistor T2 through the contact hole in the first interlayer insulating layer 113a. The first drain electrode DE1 may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

The first source electrode SE1 is disposed on the first passivation layer 114a. The first source electrode SE1 is electrically connected to the first active layer ACT1 through the contact hole in the first passivation layer 114a, the second interlayer insulating layer 113b, and the first interlayer insulating layer 113a. Further, the first source electrode SE1 may be electrically connected to the data line DL. For example, the first source electrode SE1 may be integrally formed with the data line DL. The first source electrode SE1 may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

Next, the second transistor T2 is disposed in each of the plurality of sub-pixels SP on the buffer layer 111. The second transistor T2 may be disposed between the plurality of data lines DL and the substrate 110 and electrically connected to the driving transistor DT. The second transistor T2 is a transistor for compensating for a threshold voltage of the driving transistor DT, and may be referred to as a sensing transistor. The second transistors T2 of the plurality of sub-pixels SP may be disposed in a row along a portion of a protruding portion of the scan line SL extending in the column direction. For example, the second transistors T2 of the plurality of sub-pixels SP on one side of the scan line SL may be disposed to correspond to the portion of the protruding portion of the scan line SL extending in the column direction, and the second transistors T2 of the plurality of sub-pixels SP on the other side of the scan line SL may be disposed to correspond to the protruding portion of the scan line SL. Accordingly, a plurality of second transistors T2 disposed in one pixel region UPA may be disposed in a column in the column direction.

The second transistor T2 includes a second active layer ACT2, a second gate electrode GE2, a second source electrode SE2, and a second drain electrode DE2.

The second active layer ACT2 is disposed between the buffer layer 111 and the gate insulating layer 112. The second active layer ACT2 may be made of a semiconductor material such as an oxide semiconductor, amorphous silicon, or polysilicon, but is not limited thereto.

In this case, the second active layers ACT2 of the plurality of adjacent sub-pixels SP may be connected to each other. For example, the second active layers ACT2 of the first sub-pixel SP1, the second sub-pixel SP2, and the third sub-pixel SP3 disposed on one side of the scan line SL may extend in the column direction and may be connected to each other, and may be connected together to the second drain electrode DE2 disposed in the first sub-pixel SP1. Further, the second active layers ACT2 of the first sub-pixel SP1, the second sub-pixel SP2, and the third sub-pixel SP3 disposed on the other side of the scan line SL may also extend in the column direction and may be connected to each other, and may be connected together to the second drain electrode DE2 disposed in the first sub-pixel SP1. That is, since connecting portions which connect channel regions of the second active layers ACT2 of the plurality of sub-pixels SP and the reference line RL are made of a transparent material of the second active layer ACT2 instead of an opaque conductive material, transmittance at the outermost edge of the pixel region UPA may be enhanced. Further, since the connecting portions which connect the channel regions of the second active layers ACT2 of the plurality of sub-pixels SP and the reference line RL are made of the material of the second active layer ACT2, the contact holes may be eliminated, and the structure of the pixel region UPA may be simplified. The sub-pixel may be a concept including a main pixel and a redundancy pixel.

The second gate electrode GE2 is disposed between the gate insulating layer 112 and the first interlayer insulating layer 113a. The second gate electrode GE2 may be electrically connected to the scan line SL. For example, the second gate electrode GE2 may be integrally formed with and electrically connected to the protruding portion of the scan line SL. The second gate electrode GE2 may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

The second source electrode SE2 is disposed between the first interlayer insulating layer 113a and the second interlayer insulating layer 113b. The second source electrode SE2 is electrically connected to the second active layer ACT2 through the contact hole in the first interlayer insulating layer 113a and the gate insulating layer 112. Further, the second source electrode SE2 may be integrally formed with the driving source electrode DSE and electrically connected to the driving source electrode DSE. The second source electrode SE2 may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

The second drain electrode DE2 is disposed between the first passivation layer 114a and a second passivation layer 114b. The second drain electrode DE2 is electrically connected to the second active layer ACT2 through the contact hole formed in the first passivation layer 114a, the second interlayer insulating layer 113b, the first interlayer insulating layer 113a, and the gate insulating layer 112. The second drain electrode DE2 may be integrally formed with the reference line RL and electrically connected to the reference line RL. The second drain electrode DE2 may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

Next, the storage capacitor Cst is disposed on the gate insulating layer 112. The storage capacitor Cst may be disposed between the plurality of data lines DL and the driving transistor DT. The storage capacitor Cst may store a potential difference between the driving gate electrode DGE and the driving source electrode DSE of the driving transistor DT while the light-emitting element 120 emits light, and may allow a constant driving current to be supplied to the light-emitting element 120. The storage capacitor Cst may include a first capacitor electrode C1 electrically connected to the driving gate electrode DGE and a second capacitor electrode C2 electrically connected to the driving source electrode DSE, and thus may maintain a constant voltage between the driving gate electrode DGE and the driving source electrode DSE

Specifically, the first capacitor electrode C1 is disposed on the gate insulating layer 112. The first capacitor electrode C1 may be integrally formed with the driving gate electrode DGE. The second capacitor electrode C2 is disposed on the first interlayer insulating layer 113a. The first capacitor electrode C1 and the second capacitor electrode C2 may be disposed to overlap each other with the first interlayer insulating layer 113a therebetween. In this case, the second capacitor electrode C2 may be integrally formed with the driving source electrode DSE. The first capacitor electrode C1 and the second capacitor electrode C2 may be composed of a single layer or multiple layers of a conductive material, for example, copper (Cu), aluminum (Al), molybdenum (Mo), nickel (Ni), titanium (Ti), chromium (Cr), or an alloy thereof, but are not limited thereto.

Next, an auxiliary electrode AE is disposed on the first passivation layer 114a. The auxiliary electrode AE is an electrode for electrically connecting the driving source electrode DSE and a first reflective electrode RE1. The driving source electrode DSE and the first reflective electrode RE1 may be electrically connected to each other through the auxiliary electrode AE. The auxiliary electrode AE may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

The low-potential power line VSS is disposed on the second interlayer insulating layer 113b. The low-potential power line VSS may be disposed in the column direction and may overlap the plurality of pixel regions UPA. The low-potential power line VSS may be electrically connected to the driving drain electrode DDE. The low-potential power line VSS may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

The reference line RL is disposed on the first passivation layer 114a. The reference line RL may be disposed in the column direction and may overlap the plurality of pixel regions UPA. The reference line RL may be disposed adjacent to the protruding portion of the scan line SL and may be electrically connected to the plurality of second transistors T2 disposed on the protruding portion of the scan line SL. The reference line RL may be composed of a single layer or multiple layers of a conductive material, for example, copper (Cu), aluminum (Al), molybdenum (Mo), nickel (Ni), titanium (Ti), chromium (Cr), or an alloy thereof, but is not limited thereto.

The plurality of data lines DL are disposed on the first passivation layer 114a. The plurality of data lines DL may extend in the column direction and overlap the plurality of pixel regions UPA. The plurality of data lines DL may be disposed on the driving transistors DT and th storage capacitors Cst and overlap the driving transistors DT and the storage capacitors Cst.

Next, the second passivation layer 114b is disposed on the driving transistor DT, the first transistor T1, the second transistor T2, the storage capacitor Cst, the reference line RL, and the data line DL. The second passivation layer 114b is an insulating layer for protecting the configurations under the second passivation layer 114b, and may be composed of a single layer or multiple layers of silicon oxide (SiOₓ) or silicon nitride (SiNₓ), but is not limited thereto.

A first planarization layer 115a is disposed on the second passivation layer 114b. The first planarization layer 115a may planarize an upper portion of the substrate 110 on which the plurality of transistors and the storage capacitor Cst are disposed. The first planarization layer 115a may be composed of a single layer or multiple layers, and may be made of, for example, a photoresist or an acrylic-based organic material, but is not limited thereto.

Meanwhile, although not shown in the drawing, an additional passivation layer may be disposed on the first planarization layer 115a. For example, a passivation layer composed of a single layer or multiple layers of silicon oxide (SiOₓ) or silicon nitride (SiNₓ) may be formed on the first planarization layer 115a to protect the configurations under the passivation layer.

Next, a plurality of first reflective electrodes RE1 are disposed on the first planarization layer 115a. The plurality of first reflective electrodes RE1 may be respectively disposed in the plurality of sub-pixels SP, and may simultaneously reflect light emitted from the light-emitting element 120 to the outside of the display device 100 while electrically connecting the driving transistor DT and the light-emitting element 120. The plurality of first reflective electrodes RE1 may be disposed adjacent to the driving source electrodes DSE in the plurality of sub-pixels SP, respectively. The plurality of first reflective electrodes RE1 may be made of an opaque conductive material with high reflection efficiency such as titanium (Ti), gold (Au), silver (Ag), copper (Cu), or an alloy thereof, but are not limited thereto.

A second reflective electrode RE2 and the high-potential power line VDD are disposed on the first planarization layer 115a. The second reflective electrode RE2 and the high-potential power line VDD are integrally formed, and may reflect the light emitted from the light-emitting element 120 to the outside of the display device 100 while supplying a high-potential power voltage to the light-emitting element 120. The second reflective electrodes RE2 of the plurality of sub-pixels SP may be connected to each other and integrally formed. The second reflective electrode RE2 and high-potential power line VDD may extend in the column direction and may be disposed to overlap the light-emitting element 120. The second reflective electrode RE2 and the high-potential power line VDD may be disposed to overlap the plurality of data lines DL, the reference line RL, and the low-potential power line VSS. The second reflective electrode RE2 and the high-potential power line VDD may be made of an opaque conductive material with high reflection efficiency such as titanium (Ti), gold (Au), silver (Ag), copper (Cu), or an alloy thereof, but are not limited thereto.

A third passivation layer 114c is disposed on the plurality of first reflective electrodes RE1 and second reflective electrodes RE2. The third passivation layer 114c is an insulating layer for protecting the configurations under the third passivation layer 114c, and may be composed of a single layer or multiple layers of silicon oxide (SiOₓ) or silicon nitride (SiNₓ), but is not limited thereto.

An adhesive layer AD is disposed on the third passivation layer 114c. The adhesive layer AD may be formed on the entire surface of the substrate 110 and may fix the light-emitting element 120 disposed on the adhesive layer AD. The adhesive layer AD may be made of a photocurable adhesive material which can be cured by light. For example, the adhesive layer AD may be selected from one of an adhesive polymer, an epoxy resist, a UV resin, a polyimide-based material, an acrylate-based material, a urethane-based material, and polydimethylsiloxane (PDMS), but is not limited thereto.

The plurality of light-emitting elements 120 are respectively disposed in the plurality of sub-pixels SP on the adhesive layer AD. The light-emitting elements 120 may be disposed on the plurality of data lines DL and electrically connected to the driving transistor DT. The light-emitting elements 120 are elements which emit light by current, and may include a red light-emitting element 120 which emits red light, a green light-emitting element 120 which emits green light, and a blue light-emitting element 120 which emits blue light, and light of various colors including white may be implemented by a combination thereof. For example, the light-emitting element 120 may be a light-emitting diode (LED) or a micro-LED, but is not limited thereto.

The red light-emitting element 120R may be disposed in the first sub-pixel SP1, the green light-emitting element 120G may be disposed in the second sub-pixel SP2, and the blue light-emitting element 120B may be disposed in the third sub-pixel SP3. The plurality of light-emitting elements 120 disposed in one pixel region UPA may be disposed in a row in the column direction. Further, the plurality of light-emitting elements 120 may be disposed to overlap the second reflective electrodes RE2 in the plurality of sub-pixels SP, respectively.

Each of the plurality of light-emitting elements 120 includes a first semiconductor layer 121, a light-emitting layer 122, a second semiconductor layer 123, a first electrode 124, a second electrode 125, and an encapsulation film 126.

The first semiconductor layer 121 is disposed on the adhesive layer AD, and the second semiconductor layer 123 may be disposed on the first semiconductor layer 121. The first semiconductor layer 121 and the second semiconductor layer 123 may be layers formed by doping a specific material with n-type and p-type impurities. For example, each of the first semiconductor layer 121 and the second semiconductor layer 123 may be a layer in which a material such as gallium nitride (GaN), indium aluminum phosphide (InAlP), gallium arsenide (GaAs), or the like is doped with n-type or p-type impurities. Further, the p-type impurities may be magnesium, zinc (Zn), beryllium (Be), or the like, and the n-type impurities may be silicon (Si), germanium, tin (Sn), or the like, but are not limited thereto,

The light-emitting layer 122 is disposed between the first semiconductor layer 121 and the second semiconductor layer 123. The light-emitting layer 122 may emit light by receiving holes and electrons from the first semiconductor layer 121 and the second semiconductor layer 123. The light-emitting layer 122 may be formed in a single-layer or multi-quantum well (MQW) structure, and made of, for example, indium gallium nitride (InGaN), gallium nitride (GaN), or the like, but is not limited thereto.

The first electrode 124 is disposed on the first semiconductor layer 121. The first electrode 124 is an electrode for electrically connecting the driving transistor DT and the first semiconductor layer 121. In this case, the first semiconductor layer 121 may be a semiconductor layer doped with n-type impurities, and the first electrode 124 may be a cathode. The first electrode 124 may be disposed on an upper surface of the first semiconductor layer 121 exposed from the light-emitting layer 122 and the second semiconductor layer 123. The first electrode 124 may be composed of a conductive material, for example, a transparent conductive material such as indium tin oxide (ITO), indium zinc oxide (IZO), or the like, or an opaque conductive material such as titanium (Ti), gold (Au), silver (Ag), copper (Cu), or an alloy thereof, but is not limited thereto.

The second electrode 125 is disposed on the second semiconductor layer 123. The second electrode 125 may be disposed on an upper surface of the second semiconductor layer 123. The second electrode 125 is an electrode for electrically connecting the high-potential power line VDD and the second semiconductor layer 123. In this case, the second semiconductor layer 123 may be a semiconductor layer doped with the p-type impurities, and the second electrode 125 may be an anode. The second electrode 125 may be composed of a conductive material, for example, a transparent conductive material such as indium tin oxide (ITO), indium zinc oxide (IZO), or the like, or an opaque conductive material such as titanium (Ti), gold (Au), silver (Ag), copper (Cu), or an alloy thereof, but is not limited thereto.

Next, the encapsulation film 126 surrounding the first semiconductor layer 121, the light-emitting layer 122, the second semiconductor layer 123, the first electrode 124, and the second electrode 125 is disposed. The encapsulation film 126 may be made of an insulating material and may protect the first semiconductor layer 121, the light-emitting layer 122, and the second semiconductor layer 123. Further, since a contact hole which exposes the first electrode 124 and the second electrode 125 is formed in the encapsulation film 126, a first connection electrode CE1 and a second connection electrode CE2 may be electrically connected to the first electrode 124 and the second electrode 125.

Meanwhile, a portion of the side surface of the first semiconductor layer 121 may be exposed from the encapsulation film 126. The light-emitting elements 120 manufactured on the wafer may be separated from the wafer and transferred to the display panel PN. However, a portion of the encapsulation film 126 may be torn off during a process of separating the light-emitting element 120 from the wafer. For example, since the portion of the encapsulation film 126 adjacent to a lower edge of the first semiconductor layer 121 of the light-emitting element 120 may be torn off during the separation process of the light-emitting element 120 and the wafer, a portion of a lower side surface of the first semiconductor layer 121 may be exposed to the outside. Even when the lower portion of the light-emitting element 120 is exposed from the encapsulation film 126, since the first connection electrode CE1 and the second connection electrode CE2 are formed after forming a second planarization layer 115b and a third planarization layer 115c covering the side surface of the first semiconductor layer 121, short-circuit defects may be reduced.

Next, the second planarization layer 115b and the third planarization layer 115c are disposed on the adhesive layer AD and the light-emitting element 120.

The second planarization layer 115b may overlap portions of side surfaces of the plurality of light-emitting elements 120 to fix and protect the plurality of light-emitting elements 120. The portion of the encapsulation film 126, which protects the side surface of the first semiconductor layer 121 of the light-emitting element 120, that has been torn off may be covered with the second planarization layer 115b. Accordingly, it is possible to prevent contact and short-circuit defects between the connection electrodes and the first semiconductor layer 121 in the future.

The third planarization layer 115c is formed to cover the second planarization layer 115b and an upper portion of the light-emitting element 120. A contact hole through which the first electrode 124 and the second electrode 125 of the light-emitting element 120 are exposed may be formed in the third planarization layer 115c. Since the first electrode 124 and the second electrode 125 of the light-emitting element 120 are exposed from the third planarization layer 115c but the third planarization layer 115c is partially disposed in a region between the first electrode 124 and the second electrode 125, short-circuit defects may be reduced. The second planarization layer 115b and the third planarization layer 115c may be composed of a single layer or multiple layers, and may be made of, for example, a photoresist or an acrylic-based organic material, but are not limited thereto.

The first connection electrode CE1 and the second connection electrode CE2 are disposed on the third planarization layer 115c.

The first connection electrode CE1 is an electrode which electrically connects the first electrode 124 of the light-emitting element 120 and the driving transistor DT. The first connection electrode CE1 may be electrically connected to the first reflective electrode RE1 through a contact hole formed in the third planarization layer 115c, the second planarization layer 115b, and the third passivation layer 114c while being electrically connected to the first electrode 124 exposed from the third planarization layer 115c. Accordingly, the first electrode 124 and the driving source electrode DSE may be electrically connected through the first connection electrode CE1, the first reflective electrode RE1, and the auxiliary electrode AE.

The second connection electrode CE2 is an electrode which electrically connects the second electrode 125 of the light-emitting element 120 and the high-potential power line VDD. The second connection electrode CE2 may be electrically connected to the second reflective electrode RE2 and the high-potential power line VDD through the contact hole formed in the third planarization layer 115c, the second planarization layer 115b, and the third passivation layer 114c while being electrically connected to the second electrode 125 exposed from the third planarization layer 115c. Accordingly, the second electrode 125 and the high-potential power line VDD may be electrically connected through the second connection electrode CE2.

The first connection electrode CE1 and the second connection electrode CE2 may be composed of a transparent conductive material such as indium tin oxide (ITO), indium zinc oxide (IZO), or the like, but are not limited thereto.

Meanwhile, in the drawing, although the driving source electrode DSE of the driving transistor DT and the first electrode 124 of the light-emitting element 120 are shown as being electrically connected, the driving drain electrode DDE of the driving transistor DT and the second electrode 125 of the light-emitting element 120 may also be electrically connected depending on the type of driving transistor DT and the design of the pixel circuit, but the present disclosure is not limited thereto.

Next, a bank BB is disposed on the third planarization layer 115c, the first connection electrode CE1, and the second connection electrode CE2 in the pixel region UPA. The bank BB may be disposed a certain interval apart from the light-emitting elements 120. The bank BB may be disposed at a boundary between the plurality of sub-pixels SP and may cover portions of the first connection electrode CE1 and the second connection electrode CE2. The bank BB may be disposed spaced apart from the transmission region TA. The bank BB may be made of an opaque material, for example, a black resin so that color mixing between the plurality of sub-pixels SP is reduced, but is not limited thereto.

A protective layer 116 is disposed on the first connection electrode CE1, the second connection electrode CE2, and the bank BB. The protective layer 116 is a layer for protecting the configurations under the protective layer 116. The protective layer 116 may be composed of a single layer or multiple layers, and may be made of, for example, benzocyclobutene, a light-transmitting epoxy, a photoresist, an acrylic-based organic material, or an inorganic material such as silicon oxide (SiOₓ) or silicon nitride (SiNₓ), or the like, but is not limited thereto.

Meanwhile, the plurality of sub-pixels SP may be disposed to overlap the plurality of lines to secure the area of the transmission region TA. In this case, driving current fluctuations may occur in each of the plurality of sub-pixels SP due to some lines. For example, the driving transistor DT and the storage capacitor Cst of each of the plurality of sub-pixels SP may be coupled to the data line DL by overlapping the data line DL. In this case, the voltage of the driving gate electrode DGE may fluctuate due to the data line DL to which a different voltage is applied for each frame. The driving current flowing to the light-emitting element 120 may fluctuate while the voltage of the driving gate electrode DGE fluctuates, and since a change in luminance due to cross talk occurs, display quality may deteriorate.

Accordingly, in the display device 100 according to one or more embodiments of the present disclosure, the voltage fluctuations of the driving gate electrode DGE due to the data line DL may be reduced by adjusting a thickness of the insulating layer in consideration of the dielectric constants of the insulating layers disposed between the storage capacitor Cst and the driving transistor DT, and the data line DL. For example, inorganic insulating films disposed on the substrate 110, that is, insulating layers such as the buffer layer 111, the gate insulating layer 112, the first interlayer insulating layer 113a, and the second passivation layer 114b may be formed with a thickness of several thousand angstroms (Å). However, since the first passivation layer 114a and the second interlayer insulating layer 113b, which are insulating layers disposed between the data line DL and the storage capacitor Cst, are formed with a thickness of at least several micrometers (um) unlike other insulating layers, the voltage fluctuations of the driving transistor DT due to the data line DL may be minimized or at least reduced. Accordingly, the thickness of the insulating layer between the data line DL and the storage capacitor Cst may be thicker than the thickness of the buffer layer 111, the thickness of the gate insulating layer 112, the thickness of the first interlayer insulating layer 113a, and the thickness of the second passivation layer 114b.

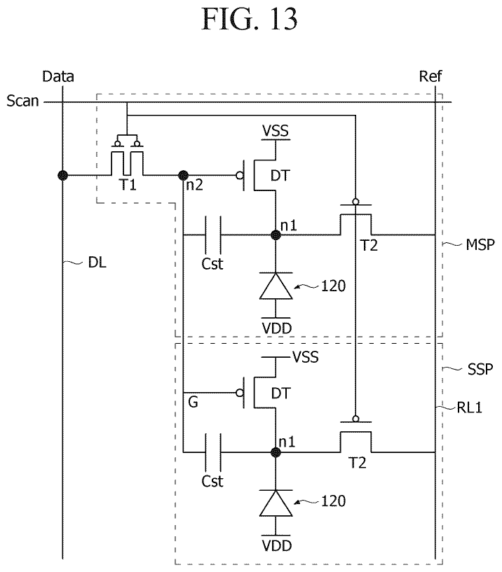

FIG. 13 is a pixel circuit diagram of the display device according to one or more embodiments of the present disclosure.

Referring to FIG. 13, the pixel circuit of the main pixel MSP and the pixel circuit of the redundancy pixel SSP may share the first transistor T1.

The pixel circuit of the main pixel MSP includes the light-emitting element 120, the driving transistor DT which drives the light-emitting element 120, the first transistor T1, the second transistor T2, and the capacitor Cst. The transistors DT, T1, and T2 may be implemented as p-type transistors, but are not limited thereto.

The pixel circuit is connected to constant voltage nodes to which a direct current voltage (or a constant voltage) is applied such as the data line DL to which a data voltage Data is applied, the scan line to which a gate signal Scan is applied, a VDD node to which a pixel driving voltage (EVDD) is applied, a VSS node to which a pixel base voltage (EVSS) is applied, and the like. The constant voltage nodes are connected to power lines disposed on the display panel PN, and the power lines may be connected to all sub-pixels in common.

The driving transistor DT includes a first electrode connected to a first node n1, a gate electrode connected to a second node n2, and a second electrode connected to the VSS node. The light-emitting element 120 includes an anode electrode connected to the VDD node and a cathode electrode connected to the first node n1. The light-emitting element 120 may be a micro-LED, but is not limited thereto. The capacitor Cst is connected between the first node n1 and the second node n2 to charge a gate-source voltage of the driving transistor DT.

The first transistor T1 is connected between the data line DL to which the data voltage Vdata is applied and the second node n2, and is turned on in response to a gate-on voltage of a gate signal SCAN. When the first transistor T1 is turned on, the data voltage is applied to the second node n2. The first transistor T1 includes a first electrode connected to the data line DL, a second electrode connected to the second node n2, and a gate electrode connected to the scan line SL to which the gate signal SCAN is applied. The first transistor T1 may be implemented in a dual-gate structure in which two transistors are connected in series to reduce a leakage current.

In this case, since the driving transistor DT of the redundancy pixel SSP is also connected to the second node n2, the data voltage may be simultaneously applied to the gate electrode of the driving transistor DT of the main pixel MSP and the gate electrode of the driving transistor DT of the redundancy pixel SSP. According to one or more embodiments, since the main pixel MSP and the redundancy pixel SSP share the first transistor T1, light transmittance may be increased by reducing the number of transistors.

The second transistor T2 is connected between a sensing line RL1 to which a reference voltage Vref is applied and the first node n1, and is turned on in response to the gate-on voltage of the gate signal SCAN. When the second transistor T2 is turned on, the first node n1 may be electrically connected to the sensing line RL1. The second transistor T2 includes a first electrode connected to the first node n1, a second electrode connected to the sensing line RL1, and a gate electrode connected to the scan line SL to which the gate signal SCAN is applied.

The sensing line RL1 may be connected to a sensing channel of the data driver DD. An analog-to-digital converter of the sensing channel may be connected to a compensation circuit of the timing controller TC. An external compensation circuit includes an ADC connected to the sensing line, and a compensation circuit which modulates the pixel data with a compensation value selected based on digital data input from the ADC. A current or voltage sensed through the sensing line RL1 is converted into digital data by the ADC and input to the compensation circuit of the timing controller TC. The external compensation circuit may compensate for a deviation (or a change) in the electrical characteristics of the driving transistor DT in each of the pixels in real time by sensing the electrical characteristics, for example, a threshold voltage and mobility, of the driving transistor DT used as a driving element of the light-emitting element 120 in each of the sub-pixels through the sensing line RL1, and modulating the pixel data (the digital data) of the input image by the deviation (or the change) in the electrical characteristics of the driving transistor DT.

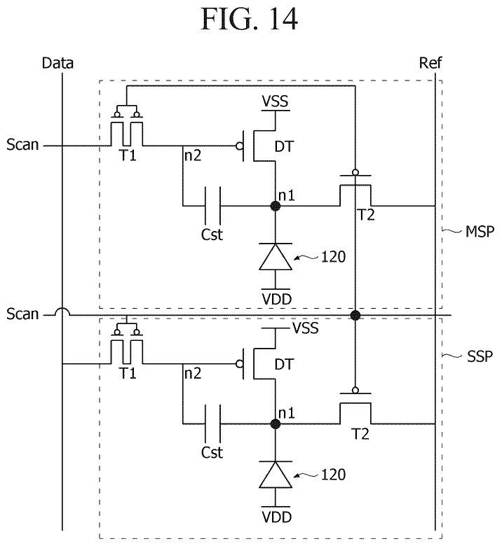

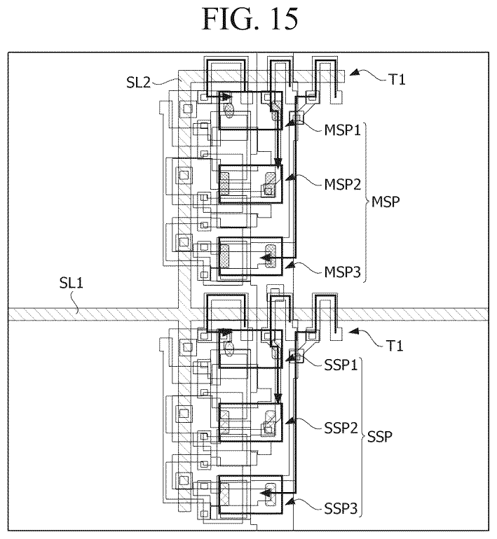

FIG. 14 is a pixel circuit diagram of a display device according to one or more other embodiments of the present disclosure. FIG. 15 is an enlarged plan view of a display region of the display device according to one or more other embodiments of the present disclosure.

Referring to FIG. 14, a pixel circuit of a main pixel MSP and a pixel circuit of a redundancy pixel SSP may each have a first transistor T1. Accordingly, a first transistor T1 of the main pixel MSP and a first transistor T1 of the redundancy pixel SSP may be simultaneously turned on in response to a scan signal. The first transistor T1 of the main pixel MSP may apply a data voltage to a gate electrode of a driving transistor DT of the main pixel MSP, and the first transistor T1 of the redundancy pixel SSP may apply a data voltage to a gate electrode of a driving transistor DT of the redundancy pixel SSP.

Referring to FIG. 15, the embodiment is similar to the embodiment of FIG. 3 described above in that a plurality of sub-pixels are disposed in the second direction, but there is a difference in that the main pixels MSP and the redundancy pixels SSP are not alternately disposed.

Scan lines may include a first scan line SL1 extending in the first direction and a second scan line SL2 branching from the first scan line SL1. The second scan line SL2 may have a shorter length in the first direction than the first scan line SL1.

The main pixels MSP may be disposed on one side of the first scan line SL1. The main pixels MSP may be disposed between the first scan line SL1 and the second scan line SL2. The main pixels MSP may be disposed in the order of a first main pixel MSP1, a second main pixel MSP2, and a third main pixel MSP3.

The redundancy pixels SSP may be disposed on the other side of the first scan line SL1. The redundancy pixels SSP may be disposed in the order of a first redundancy pixel SSP1, a second redundancy pixel SSP2, and a third redundancy pixel SSP3.

The first transistor T1 disposed to overlap the second scan line SL2 may apply a da voltage to the first main pixel MSP1, the second main pixel MSP2, and the third main pixel MSP3. An arrow indicates a data voltage application direction or the flow of current.

The first transistor T1 disposed to overlap the first scan line SL1 may apply a data voltage to the first redundancy pixel SSP1, the second redundancy pixel SSP2, and the third redundancy pixel SSP3. An arrow indicates a direction of data signals or the flow of current.

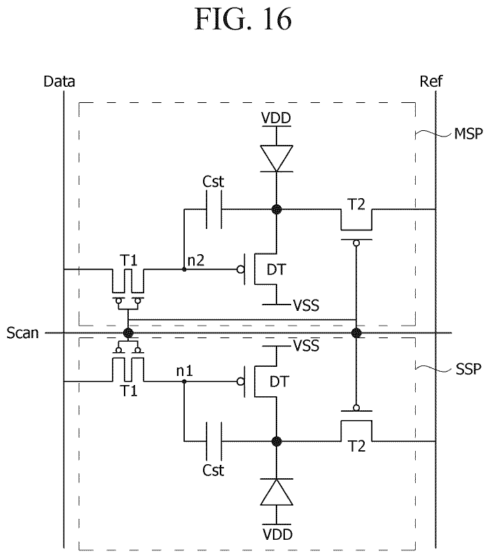

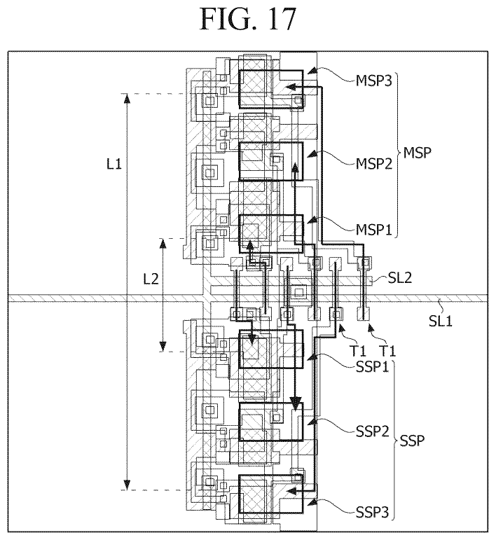

FIG. 16 is a pixel circuit diagram of a display device according to one or more other embodiments of the present disclosure. FIG. 17 is an enlarged plan view of a display region of the display device according to one or more other embodiments of the present disclosure.

Referring to FIG. 16, since a pixel circuit of a main pixel and a pixel circuit of a redundancy pixel are the same as the circuit structure in FIG. 14 except for being disposed to face each other, the detailed description thereof will be omitted.

Referring to FIG. 17, the main pixels and the redundancy pixels may be disposed symmetrically to each other based on a scan line. For example, based on the scan line SL, the main pixels may be disposed as a first main pixel MSP1, a second main pixel MSP2, and a third main pixel MSP3 in a direction away from the scan line SL, and the redundancy pixels may be disposed as a first redundancy pixel SSP1, a second redundancy pixel SSP2, and a third redundancy pixel SSP3 in a direction away from the scan line SL.

A plurality of first transistors T1 may be disposed between the main pixels MSP and the redundancy pixels SSP. Among the plurality of first transistors T1, some may apply data signals to the main pixels MSP and some may apply data signals to the redundancy pixels SSP. In the structure, since the first main pixel MSP1 and the first redundancy pixel SSP1 which emit light of the same color are disposed relatively close while the third main pixel MSP3 and the third redundancy pixel SSP3 which emit light of the same color are disposed relatively far, intervals between the pixels are not uniform. Accordingly, image quality and readability may deteriorate.

Embodiments of the present disclosure are directed to a display device in which image quality is improved by disposing pixels of the same color at constant intervals.

Embodiments of the present disclosure can maximally or at least increasingly secure the area of a transmission region in the display device by disposing opaque components among the components of the display device so that the opaque components overlap.

Effects according to the present disclosure are not limited to the content exemplified above, and various other effects are included in the present disclosure.

Although the embodiments of the present disclosure have been described in more detail with reference to the accompanying drawings, the present disclosure is not necessarily limited to these embodiments, and may be variously modified without departing from the technical spirit of the present disclosure.

Accordingly, the embodiments disclosed in the present disclosure are not intended to limit the technical spirit of the present disclosure, but intended to describe the same, and the scope of the technical spirit of the present disclosure is not limited by these embodiments. Accordingly, it should be understood that the above-described embodiments are illustrative and not restrictive in all respects.

What is claimed is:

1. A display device, comprising:
a substrate in which a plurality of pixel regions spaced apart from each other and a plurality of transmission regions disposed between the plurality of pixel regions are defined;
a scan line extending in a first direction on the substrate; and
a plurality of data lines extending in a second direction intersecting the first direction on the substrate,
wherein each of the plurality of pixel regions includes a plurality of sub-pixels,
wherein each of the plurality of sub-pixels includes a first main pixel and a first redundancy pixel that output first light, a second main pixel and a second redundancy pixel that output second light, and a third main pixel and a third redundancy pixel that output third light, and
wherein the first main pixel, the first redundancy pixel, the second main pixel, the second redundancy pixel, the third main pixel, and the third redundancy pixel are sequentially disposed in the first direction or the second direction.

2. The display device of claim 1, wherein the first light is light in a red wavelength range,
wherein the second light is light in a green wavelength range, and
wherein the third light is light in a blue wavelength range.

3. The display device of claim 1, wherein an interval between the first main pixel and the first redundancy pixel is same as an interval between the second main pixel and the second redundancy pixel.

4. The display device of claim 1, wherein the first main pixel and the first redundancy pixel share a first transistor connected to the plurality of data lines,
wherein the second main pixel and the second redundancy pixel share a first transistor connected to the plurality of data lines, and
wherein the third main pixel and the third redundancy pixel share a first transistor connected to the plurality of data lines.

5. The display device of claim 4, further comprising a sub-scan line extending from the scan line and parallel to the scan line in the first direction,
wherein a first active layer of the first transistor extends in the second direction and overlaps the scan line and the sub-scan line.

6. The display device of claim 4, wherein each of the plurality of sub-pixels further includes:
a driving transistor disposed between the plurality of data lines and the substrate, the driving transistor electrically connected to the first transistor;
a second transistor disposed between the plurality of data lines and the substrate, the second transistor electrically connected to the driving transistor;
a storage capacitor disposed between the plurality of data lines and the driving transistor, the storage capacitor electrically connected to a gate electrode of the driving transistor; and
a light-emitting element disposed on the plurality of data lines and electrically connected to the driving transistor.

7. The display device of claim 6, wherein driving transistors of the plurality of sub-pixels are disposed in a row in the second direction.

8. The display device of claim 6, wherein second transistors of the plurality of sub-pixels are disposed in a row in the second direction.

9. The display device of claim 6, wherein the plurality of data lines are disposed on driving transistors of the plurality of sub-pixels and storage capacitors of the plurality of sub-pixels, and wherein the plurality of data lines overlap the driving transistors and the storage capacitors.

10. The display device of claim 6, further comprising a low-potential power line disposed among storage capacitors of the plurality of sub-pixels, driving transistors of the plurality of sub-pixels, and the plurality of data lines,
wherein the low-potential power line overlaps a region where the plurality of data lines are disposed.

11. The display device of claim 10, wherein the low-potential power line overlaps the driving transistors and the storage capacitors.

12. The display device of claim 10, further comprising a high-potential power line disposed between light-emitting elements of the plurality of sub-pixels and the plurality of data lines,
wherein the high-potential power line overlaps the region where the plurality of data lines are disposed.

13. The display device of claim 6, wherein driving active layers of driving transistors of the plurality of sub-pixels are connected to second active layers of second transistors of the plurality of sub-pixels.

14. The display device of claim 6, wherein second active layers of second transistors of the first main pixel, the second main pixel, and the third main pixel are connected to each other.

15. The display device of claim 10, wherein gate electrodes of the first main pixel and the first redundancy pixel are connected to each other.

16. The display device of claim 1, wherein a main pixel of the first main pixel, the second main pixel, and the third main pixel and a redundancy pixel of the first redundancy pixel, the second redundancy pixel, and the third redundancy pixel that output a same color of light are disposed adjacent to each other at constant intervals.
